(19) United States
(12) Patent Application Publication
(10) Pub. No.: US 2025/0255145 A1
(43) Pub. Date: Aug. 7, 2025

(54) DISPLAY DEVICE

(71) Applicant: LG Display Co., Ltd., Seoul (KR)

(72) Inventor: JaeGyu LEE, Chilgok-gun (KR)

(73) Assignee: LG Display Co., Ltd., Seoul (KR)

(21) Appl. No.: 18/784,447

(22) Filed: Jul. 25, 2024

(30) Foreign Application Priority Data
Feb. 6, 2024 (KR) 10-2024-0018269

(51) Int. Cl. H10K 59/80

(52) U.S. Cl. CPC H10K 59/872; H10K 59/879; H10K 59/8792

(57) ABSTRACT

A display device in one example includes a display panel having a plurality of sub pixels, a cover member disposed on the display panel, and a flexible film bonded to a top surface of the display panel at one side of the display panel and bent toward a bottom surface of the display panel. At least a part of a bottom surface of the cover member is a concave surface recessed toward a top surface of the cover member, and the top surface of the cover member has a flat shape. Accordingly, a bezel is reduced while maintaining the shape of the flexible film to bend the printed circuit board as it is. Thus, light leakage and luminance degradation, which can be generated at an outer periphery of the display device, can be minimized.

### CROSS-REFERENCE TO RELATED APPLICATIONS

This application claims priority to Korean Patent Application No. 10-2024-0018269 filed on Feb. 6, 2024, in the Korean Intellectual Property Office, the entire contents of which is hereby expressly incorporated by reference into the present application.

### BACKGROUND

### Field

The present disclosure relates to a display device, and more particularly to a display device with a reduced bezel part.

### Discussion of the Related Art

A display device can be used for various types of devices, such as TVs, monitors, tablet computers, navigations, game players, and mobile phones. As such a display device, various types of display devices, such as a liquid crystal display (LCD) device or an organic light emitting display (OLED) device, have been used.

In the meantime, a flexible film and a printed circuit board which can be bonded on the substrate are disposed on one side of the display device. An area in which the flexible film and the printed circuit board are disposed is an area in which images are not actually displayed, and when the area is disposed on the front surface of the display device, a bezel to cover the corresponding area is necessary. Therefore, in order to minimize the bezel area, a technique of bending the flexible film to dispose the printed circuit board on a rear side of the substrate is being developed.

### SUMMARY OF THE DISCLOSURE

An object to be achieved by the present disclosure is to provide a display device in which when a flexible film is bent to dispose the printed circuit board on a rear surface of the display panel, a bezel is reduced while maintaining a protruding amount of the bent portion of the flexible film as it is.

Another object to be achieved by the present disclosure is to provide a display device in which a distortion of a screen is minimized.

Still another object to be achieved by the present disclosure is provide a display device in which light leakage generated at an outer peripheral portion of the display device and the luminance degradation thereby are minimized.

Objects of the present disclosure are not limited to the above-mentioned objects, and other objects, which are not mentioned above, can be clearly understood by those skilled in the art from the following descriptions.

According to an aspect of the present disclosure, a display device includes a display panel including a plurality of sub pixels; a cover member disposed on the display panel; a flexible film bonded to a top surface of the display panel at one side of the display panel and bent toward a bottom surface of the display panel, where at least a part of a bottom surface of the cover member is a concave surface recessed toward a top surface of the cover member and the top surface of the cover member has a flat shape. Accordingly, a bezel is reduced while maintaining a shape of the flexible film to bend the printed circuit board as it is and light leakage and a luminance degradation thereby which can be generated at an outer periphery of the display device can be minimized.

Other detailed matters of the example embodiments are included in the detailed description and the drawings.

According to an aspect of the present disclosure, when a flexible film is bent, stress applied to the bent portion is minimized to minimize or eliminate a crack which can be generated thereby.

According to an aspect of the present disclosure, the bezel area of the display device is reduced while maintaining a protruding amount of a curvature portion of the flexible film so as to minimize the applied stress.

According to an aspect of the present disclosure, at least a part of the display panel has a curved shape so that a distortion of a screen which can be caused on an edge portion of the display device, specifically, on both side surfaces of the display device can be suppressed.

According to an aspect of the present disclosure, at least a part of the display panel has a curved shape so that light leakage or luminance degradation which can be caused by light discharged from the display panel to be directed to both side surfaces, rather than the front surface direction, is minimized.

The effects according to the present disclosure are not limited to the contents exemplified above, and more various effects are included in the present specification.

The effects of the present disclosure are not limited to the aforementioned effects, and other effects, which are not mentioned above, will be apparently understood to a person having ordinary skill in the art from the following description.

The objects to be achieved by the present disclosure, the means for achieving the objects, and the effects of the present disclosure described above do not specify essential features of the claims and, thus, the scope of the claims is not limited to the disclosure of the present disclosure.

### BRIEF DESCRIPTION OF THE DRAWINGS

The above and other aspects, features and other advantages of the present disclosure will be more clearly understood from the following detailed description taken in conjunction with the accompanying drawings, in which:

FIG. 1 is a schematic plan view of a display device according to an example embodiment of the present disclosure;

FIG. 2 is a cross-sectional view of a display device according to an example embodiment of the present disclosure;

FIG. 3 is an enlarged view of an area A of FIG. 2;

FIG. 4A is a plan view illustrating a display area of a display device according to an example embodiment of the present disclosure in a non-driving state;

FIG. 4B is a plan view illustrating a display area of a display device according to an example embodiment of the present disclosure in a driving state;

FIG. 5 is a cross-sectional view of a display device according to another example embodiment of the present disclosure;

FIG. 6 is an enlarged view of an area A′ of FIG. 5;

FIG. 7 is a cross-sectional view of a display device according to still another example embodiment of the present disclosure; and

FIG. 8 is a cross-sectional view of a display device according to still another example embodiment of the present disclosure.

### DETAILED DESCRIPTION OF THE EMBODIMENTS

Advantages and characteristics of the present disclosure and a method of achieving the advantages and characteristics will be clear by referring to example embodiments described below in detail together with the accompanying drawings. However, the present disclosure is not limited to the example embodiments disclosed herein but will be implemented in various forms. The example embodiments are provided by way of example only so that those skilled in the art can fully understand the disclosures of the present disclosure and the scope of the present disclosure.

The shapes, sizes, ratios, angles, numbers, and the like illustrated in the accompanying drawings for describing the example embodiments of the present disclosure are merely examples, and the present disclosure is not limited thereto. Like reference numerals generally denote like elements throughout the specification. Further, in the following description of the present disclosure, a detailed explanation of known related technologies can be omitted to avoid unnecessarily obscuring the subject matter of the present disclosure. The terms such as “including,” “having,” and “consist of” used herein are generally intended to allow other components to be added unless the terms are used with the term “only”. Any references to singular can include plural unless expressly stated otherwise.

Components are interpreted to include an ordinary error range even if not expressly stated.

When the position relation between two parts is described using the terms such as “on”, “above”, “over”, “below”, “under”, and “next”, one or more parts can be positioned between the two parts unless the terms are used with the term “immediately” or “directly”.

When an element or layer is disposed “on” another element or layer, another layer or another element can be interposed directly on the other element or therebetween.

Although the terms “first”, “second”, and the like are used for describing various components, these components are not confined by these terms. These terms are merely used for distinguishing one component from the other components and may not define order or sequence. Therefore, a first component to be mentioned below can be a second component in a technical concept of the present disclosure.

Like reference numerals generally denote like elements throughout the specification.

A size and a thickness of each component illustrated in the drawing are illustrated for convenience of description, and the present disclosure is not limited to the size and the thickness of the component illustrated.

The features of various embodiments of the present disclosure can be partially or entirely adhered to or combined with each other and can be interlocked and operated in technically various ways, and the embodiments can be carried out independently of or in association with each other. Further, the term “can” encompasses all the meanings and coverages of the term “may.”

Hereinafter, a display device according to example embodiments of the present disclosure will be described in detail with reference to accompanying drawings. All the components of each display device or apparatus according to all embodiments of the present disclosure are operatively coupled and configured.

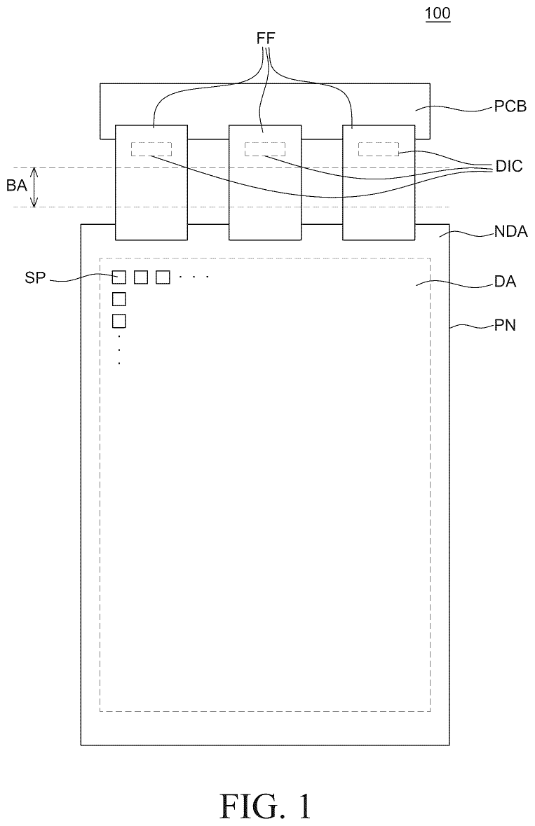

FIG. 1 is a schematic plan view of a display device according to an example embodiment of the present disclosure.

For the convenience of description, in FIG. 1, among various components of the display device 100, a display panel PN, a driving circuit (driving integrated circuit) DIC, a printed circuit board PCB, and a flexible film FF are illustrated, but it is not limited thereto.

Referring to FIG. 1, the display device 100 according to the example embodiment of the present disclosure can include the display panel PN including a plurality of sub pixels, the flexible film FF, the printed circuit board PCB, and the driving circuit DIC.

The display panel PN can include a display area DA and a non-display area NDA. The non-display area NDA can surround the display area DA entirely or in part.

The display area DA is an area in which images are displayed in the display device 100.

In the display area DA, a plurality of sub pixels SP which configures a plurality of pixels and a circuit for driving the plurality of sub pixels SP can be disposed. The plurality of sub pixels SP is a minimum unit which configures the display area DA and a display element can be disposed in each of the plurality of sub pixels SP. The plurality of sub pixels SP can configure a pixel. For example, an organic light emitting diode which includes an anode, an organic emission layer, and a cathode can be disposed in each of the plurality of sub pixels SP, but it is not limited thereto. Further, a circuit for driving the plurality of sub pixels SP can include a driving element, a wiring line, and the like. For example, the circuit can be configured by a thin film transistor, a storage capacitor, a gate line, a data line, and the like, but is not limited thereto.

The non-display area NDA is an area where no image is displayed.

The non-display a NDA encloses a quadrangular display area DA, but the shapes and placements of the display area DA and the non-display area NDA are not limited to the example illustrated in FIG. 1.

In other words, the display area DA and the non-display area NDA can have shapes suitable for a design of an electronic device including the display device 100. For example, an example shape of the display area DA can be a pentagon, a hexagon, a circle, or an oval.

In the non-display area NDA, various wiring lines and circuits for driving the organic light emitting diode of the display area DA can be disposed.

A flexible film FF is disposed on one side of the display panel PN. Further, the flexible film FF is bonded onto a top surface of the display panel PN and is bent toward a bottom surface of the display panel PN to be connected to the printed circuit board PCB disposed below the display panel PN. Therefore, the flexible film FF can include a bending area BA and the bending area BA can be an area in which a bent state is maintained.

The printed circuit board PCB can be attached to the other side of the flexible film FF with respect to one side of the flexible film FF at which the flexible film FF and the display panel PN are connected.

The printed circuit board PCB can transmit various signals to a thin film transistor formed on the display panel PN. For example, a timing controller, etc. can be disposed on the printed circuit board PCB. The timing controller can supply various signals to the driving circuit. For example, the timing controller generates a data driver control signal and a gate driver control signal to supply the signals to the driving circuit DIC.

In the flexible film FF, a driving circuit DIC can be mounted. The driving circuit DIC generates a data signal or a gate signal corresponding to a driving power or various signals which are transmitted from the printed circuit board PCB and supplies the data signal or the gate signal to the display panel PN. To this end, the driving circuit DIC can include both a data driver which generates a data signal and a gate driver which generates a scan signal or the driving circuit can include the data driver and the gate driver can be embedded in the display panel. In this case, the flexile film FF can transmit signals output from the printed circuit board PCB to the driving circuit DIC or transmit signals output from the driving circuit DIC to the display panel PN. The flexible film FF can be attached onto a pad unit provided in a non-display area NDA of the display panel PN using an anisotropic conducting film ACF.

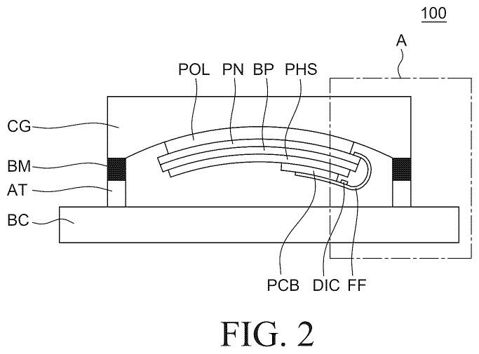

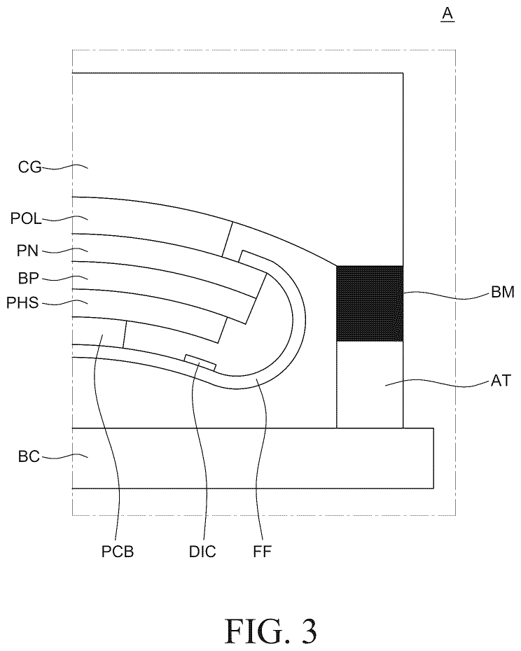

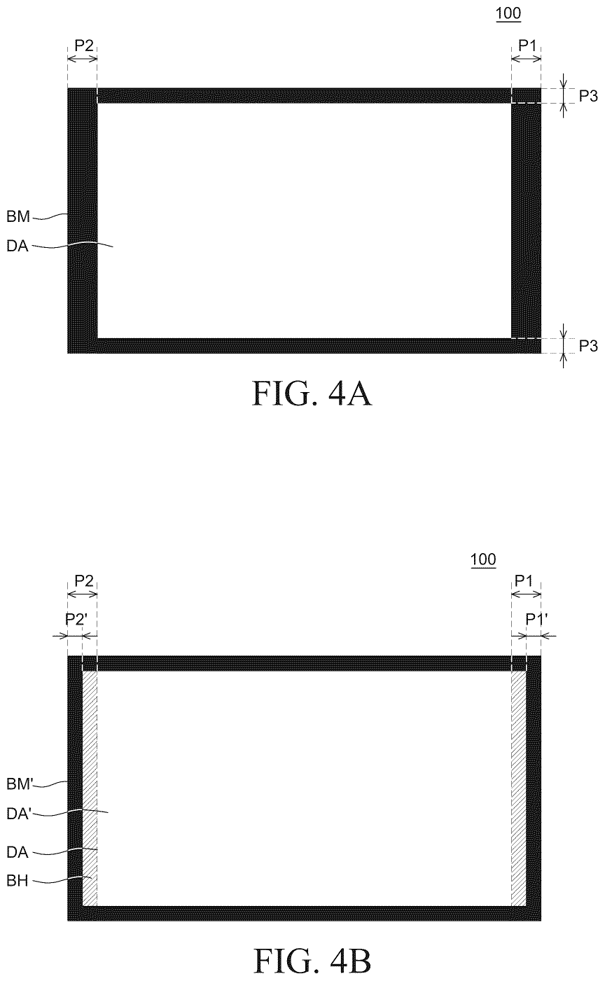

FIG. 2 is a schematic cross-sectional view of a display device according to an example embodiment of the present disclosure. FIG. 3 is an enlarged view of an area A of FIG. 2. FIG. 4A is a plan view illustrating a display area before driving a display device according to an example embodiment of the present disclosure and FIG. 4B is a plan view illustrating a display area during the driving.

First, referring to FIGS. 2 and 3, the display device 100 includes a cover member CG disposed on the display panel PN. At least a part of a bottom surface of the cover member CG is a concave surface recessed toward a top surface of the cover member CG. Further, a top surface of the cover member CG has a flat shape. At this time, the bottom surface of the cover member CG refers to a surface adjacent to the display panel PN and a top surface refers to a rear surface thereof. Hereinafter, for the convenience of description, in the present disclosure, the top surface refers to a surface adjacent to the cover member CG and the bottom surface refers to an opposite surface.

The concave surface of the cover member CG can be recessed from an area in which the flexible film FF is disposed and an opposite area of the area in which the flexible film FF is disposed toward a center portion. For example, the concave surface of the cover member CG can have a recessed shape such that the closer to the center, the more adjacent to the top surface. The display panel PN can be disposed on the bottom surface of the cover member CG and the printed circuit board PCB can be disposed on the bottom surface of the display panel PN. At this time, the printed circuit board PCB can be disposed on the flexible film FF bonded onto one side portion of the display panel PN and is bent toward the bottom surface of the display panel PN. For example, as the flexible film FF is bent toward the bottom surface of the display panel PN, the printed circuit board PCB disposed on one side of the flexible film FF can also be disposed on the bottom surface of the display panel PN.

An overall shape of the display panel PN disposed below the cover member CG can correspond to a shape of the bottom surface of the cover member CG. Further, the display panel PN can be bonded to a concave surface of the bottom surface of the cover member CG. Specifically, the display panel PN is bonded to the concave surface of the cover member CG to have a shape recessed toward the center portion from both side portions of the display panel PN. At this time, the recessed shape refers to a shape curved toward the center portion of the display panel PN to be adjacent to the top surface of the cover member CG. Further, both a top surface and a bottom surface of the display panel PN can be concave surfaces curved to be adjacent to the top surface of the cover member CG.

The display panel PN is a panel in which images are implemented. Display elements for implementing images and circuit units for driving the display elements can be disposed in the display panel. The circuit unit can include various thin film transistors, capacitors, wiring lines, and driving ICs for driving the organic light emitting diode. For example, the circuit unit can include various configurations, such as a driving thin film transistor, a switching thin film transistor, a storage capacitor, a gate line, a data line, a gate driver IC, and a data driver IC, but are not limited thereto.

Specifically, the display panel PN can include flexible substrate, a thin film transistor, and an organic light emitting diode.

The flexible substrate can be a very thin plastic substrate to implement a flexibility of the organic light emitting display device 100. The flexible substrate can be formed of an insulating material having a flexibility, and for example, the flexible substrate can be an insulating plastic substrate selected from polyimide, polyethersulfone, polyethylene terephthalate, and polycarbonate. However, the present disclosure is not limited thereto. The plastic substrate has a relatively weak barrier characteristic against moisture or oxygen so that in order to compensate therefor, the plastic substrate can have a structure in which a plastic film and an inorganic film are laminated. For example, the flexible substrate can have a multi-layered structure in which a first plastic film, an inorganic film, and a second plastic film are sequentially laminated, but is not limited thereto.

A thin film transistor for driving an organic light emitting diode can be disposed on the flexible substrate. The thin film transistor can be disposed in each of the plurality of pixel areas. For example, the driving thin film transistor can include a gate electrode, a semiconductor layer, a source electrode, and a drain electrode. Further, the thin film transistor can further include a gate insulating layer which insulates the gate electrode from the semiconductor layer and an interlayer insulating layer which insulates the gate electrode from the source and drain electrodes.

A planarization layer can be disposed on the thin film transistor to planarize an upper surface.

The organic light emitting diode can be disposed on the planarization layer. The organic light emitting diode can include an anode, a cathode, and an organic emission layer disposed therebetween. In the organic light emitting diode, holes injected from the anode and electrons injected from the cathode are coupled on the organic emission layer to emit light. The image can be displayed using the light emitted as described above.

In the display device 100 according to the example embodiment of the present disclosure, the display panel PN can have a recessed shape to be adjacent to the top surface of the cover member CG toward the center portion from both side portions. Therefore, all configurations included in the display panel PN, such as an organic light emitting diode also have a recessed shape toward the center portion. As described above, the display panel PN is disposed to have a recessed shape so that light emitted from the display panel PN can be emitted not only to a front surface direction of the display device 100, but also to a side surface direction. A polarization plate POL can be disposed between the display panel PN and the cover member CG.

The polarization plate POL can suppress the reflection of the external light on the display area DA. When the display device 100 is used at the outside, external natural light enters to be reflected by a reflective layer included in an anode of a light emitting diode or reflected by an electrode which is formed of a metal and is disposed below the light emitting diode. The image of the display device 100 may not be visibly recognized due to the reflected light. The polarization plate POL polarizes the light entering from the outside to a specific direction and can suppress the reflected light from being emitted to the outside of the display device 100. The polarization plate POL can be disposed on the display area DA, but is not limited thereto.

The polarization plate POL can be configured by a polarizer and a protective film which protects the polarizer and can be formed by coating a polarization material for ensuring flexibility.

In the display device 100 according to the example embodiment of the present disclosure, the polarization plate POL can be disposed between the cover member CG and the display panel PN. Therefore, a top surface of the polarization plate POL can be bonded to the bottom surface of the cover member CG and a bottom surface can be bonded to the top surface of the display panel PN. Further, the polarization plate POL can be bonded to a concave surface of the bottom surface of the cover member CG. Therefore, the top surface of the polarization plate POL can have a recessed shape so as to be adjacent to the top surface of the cover member CG toward the center portion from both side portions. The bottom surface of the polarization plate POL can have the same shape as the top surface. Therefore, the display panel PN bonded to the bottom surface of the polarization plate POL can have a center portion recessed toward the top surface of the cover member CG.

A length of a side of the polarization plate POL adjacent to the flexible film FF to an opposite side is smaller than a length of the display panel PN. For example, both side portions of the polarization plate POL can be disposed in an inside which is adjacent to the center portion than both side portions of the display panel PN. As described above, when both side portions of the polarization plate POL are disposed in an inside more than both side portions of the display panel PN, one side of the flexible film FF can be disposed on one side of the display panel PN on which the polarization plate POL is not disposed.

A back plate BP can be disposed on a bottom surface of the display panel PN.

When the substrate of the display panel PN is formed of a plastic material such as polyimide, a manufacturing process of a display device 100 is performed in a situation in which a support substrate configured by glass is disposed below the display panel PN. After completing the manufacturing process, the support substrate is separated to be released.

Even after releasing the support substrate, a component for supporting the display panel PN is required so that the back plate BP for supporting the display panel PN can be disposed on the bottom surface of the display panel PN.

The back plate BP can suppress foreign materials from being attached to the lower portion of the substrate, and can serve to buffer shocks from the outside.

In the display device 100 according to the example embodiment of the present disclosure, a top surface of the back plate BP can be in contact with the bottom surface of the display panel PN. For example, the back plate BP is disposed so as to overlap a concave surface of the bottom surface of the display panel PN. Therefore, the back plate BP can have a recessed shape so as to be adjacent to the cover member CG toward the center portion from both side portions. At this time, both the top surface and the bottom surface of the back plate BP can have a concave shape.

The back plate BP can have the same size as the display panel PN, but is not limited thereto.

A heat radiation sheet PHS can be disposed on the bottom surface of the back plate BP. The heat radiation sheet PHS serves to discharge heat generated in the display panel PN. In addition, the heat radiation sheet PHS can perform a function of protecting the bottom surface of the display device 100 from the shock.

The heat radiation sheet PHS can be formed of a material having excellent heat conductivity and mechanical strength. For example, the heat radiation sheet PHS can be formed of a metal material and have a thermal conductivity of 3000 W/mK or more and configured by copper (Cu) or stainless steel (SUS), but is not limited thereto.

The heat radiation sheet PHS can be disposed so as to be in contact with the bottom surface of the back plate BP. Therefore, a top surface of the heat radiation sheet PHS can be formed so as to correspond to a shape of a bottom surface of the back plate BP. For example, when a bottom surface of the back plate BP is formed to have a concave surface adjacent to the cover member CG toward the center portion from both side portions, the top surface of the heat radiation sheet PHS also has the same shape. Further, the bottom surface of the heat radiation sheet PHS also has the same shape as the top surface.

In the heat radiation sheet PHS, a length of one side adjacent to the flexible film FF to the other side is smaller than the back plate BP, but is not limited thereto.

A printed circuit board PCB can be disposed on the bottom surface of the heat radiation sheet PHS. The printed circuit board PCB can be disposed on one surface at one side of the flexible film FF and the other side of the flexible film FF can be attached to the display panel PN on the same surface.

The printed circuit board PCB can be disposed inside so as to be adjacent to the center portion more than one side of the heat radiation sheet PHS.

The configurations of the examples of the present disclosure can be bonded by the adhesive layer.

The adhesive layer can include an optical clear adhesive (OCA) or a pressure sensitive adhesive (PSA), but is not limited thereto.

The display device 100 according to the example embodiment of the present disclosure can further include a black matrix BM in contact with the bottom surface of the cover member CG and encloses the display panel PN.

The black matrix BM can be disposed to be spaced apart from the display panel PN. The black matrix BM can extend so as to overlap at least one side of the display panel PN.

An area of the bottom surface of the cover member CG in which the black matrix BM is disposed can be a flat surface. For example, the bottom surface of the cover member CG can further include a flat surface which encloses the concave surface. However, it is not limited thereto and the bottom surface of the cover member CG may not include a flat surface and the black matrix BM can be disposed in the concave surface of the cover member CG.

Referring to FIG. 4A, in a non-driving state of the display device 100, the black matrix BM can include a first part P1 to which the flexible film FF is adjacent, a second part P2 opposite to the first part P1, and a third part which connects the first part P1 and the second part P2. Here, the non-driving state of the display device can refer to a state in which a power of the display device is turned off. At this time, regardless of whether to actually display the image, the user can recognize the shape of the black matrix disposed in the display device as it is.

Further, widths of the first part P1 and the second part P2 of the black matrix BM can be larger than a width of the third part P3. In the first part P1 and the second part P2 of the black matrix BM, the flexible film FF can be disposed in a place adjacent thereto. At this time, the black matrix BM serves to cover the flexible film FF. The flexible film FF can include a bending area BA which is curved to bend the printed circuit board PCB to the bottom surface of the display panel PN. At this time, the bending area BA can laterally protrude. Therefore, the black matrix BM can serve to cover the bending area BA of the flexible film FF so as not to be visible in the field of view. Accordingly, in the display device 100 according to the example embodiment of the present disclosure, the widths of the first part P1 and the second part P2 of the black matrix BM to be large to sufficiently ensure the protruding margin of the bending area BA of the flexible film FF.

Referring to FIG. 4B, in a driving state of the display device 100, a first part P1′ and a second part P2′ of the black matrix BM′ which is visible to the user can be smaller than the first part P1 and the second part P2 of the black matrix BM in the non-driving state of the display device 100, respectively.

Specifically, the display device 100 according to the example embodiment of the present disclosure has a shape recessed toward the center portion from both side portions of the display panel PN. By doing this, the light discharged from the display panel PN can be directed not only to the front surface direction, but also partially to both side surface direction. Therefore, light discharged from the display panel PN while driving the display device 100 can reach an area which partially overlaps the first part P1 and the second part P2 of the black matrix BM in the non-driving state of the display device 100. By doing this, the first part P1′ and the second part P2′ of the black matrix BM′ which is visible to the user in a driving state of the display device 100 can be smaller than the first part P1 and the second part P2 which are visible to the user in the non-driving state of the display device 100. For example, the display area DA′ which is visible to the user in the driving state of the display device 100 according to the example embodiment of the present disclosure can expand more than the display area DA which is visible to the user in the non-driving state of the display device 100.

A back cover BC can be disposed on the rear surface of a surface on which the black matrix BM and the cover member CG are in contact with each other. The back cover BC can have a rectangular frame shape, but is not limited thereto. The back cover BC can be disposed on the rear surface or a rear side of the display device 100 and is bonded to the black matrix BM by means of an adhesive AT. Therefore, the back cover BC can be connected to the cover member CG through the black matrix BM.

As the size of the display device is reduced, efforts are continued to reduce a bezel area which is an outer periphery of the display area to increase an effective display screen size with the same area of the display device. Generally, in the bezel area corresponding to the non-display area, a wiring line and a driving circuit for driving the screen are disposed so that there is a limitation in minimizing the bezel area.

With regard to this, as a technique of applying a flexible substrate, such as plastic, is being developed, a flexible display device which maintains a display performance even in a curved state is being developed using the same. Together with this, in order to minimize the bezel area while ensuring an area for the wiring line and the driving circuit, a technique of minimizing the bezel area by bending the flexible film is being developed.

However, even though the flexible film is bent to dispose the printed circuit board on the rear surface of the substrate, the bending is actually performed on the flexible film so that an area which protrudes to the outside of the substrate so as not to overlap the substrate is also defined as a bezel area. Therefore, in order to minimize the bezel area, development is performed to reduce the area of the flexible film which is bent.

As described above, a size of an area which protrudes to the outside of the substrate by bending the flexible film to reduce the bezel area is physically reduced, the curvature of the flexible film is reduced, which increases a stress applied to the flexible film. For example, a tensile stress is applied to an outer surface in an area which is bent so that various components in the bent area can be cracked due to the tensile stress.

Accordingly, the display device 100 according to the example embodiment of the present disclosure includes a cover member CG which has a flat top surface and a bottom surface which is at least partially formed of a concave surface recessed toward the top surface. Further, the display panel PN can be bonded to the concave surface of the bottom surface of the cover member CG with a shape corresponding to the bottom surface of the cover member CG. Accordingly, in the driving state of the display device 100, light discharged from the display panel PN can be directed not only to the front surface direction of the display device 100, but also to the side surface direction. As described above, the light discharged from the display panel PN is directed to the side surface so that the light reaches an area which partially overlaps the black matrix BM. Therefore, the display area DA′ visible to the user in the driving state of the display device 100 can be larger than the display area DA visible to the user in the non-driving state of the display device 100. Accordingly, a bezel area which is actually visible can be reduced more than the bezel area which is actually disposed.

Therefore, in the display device according to the example embodiment of the present disclosure, a width of the black matrix BM including both side portions, for example, a first part P1 of an area to which the flexible film FF is adjacent and a second part P2 of an opposite area, in the non-driving state, can be designed to be larger than a width of the third part P3. By doing this, the protruding amount of the bending area BA of the flexible film FF which protrudes to the outside of the panel may not be physically reduced. Therefore, the stress applied to the bending area BA is reduced and the crack caused by the stress can be suppressed.

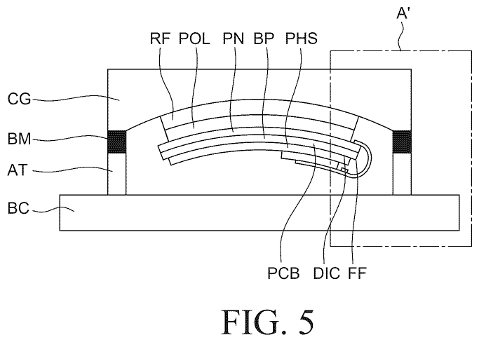

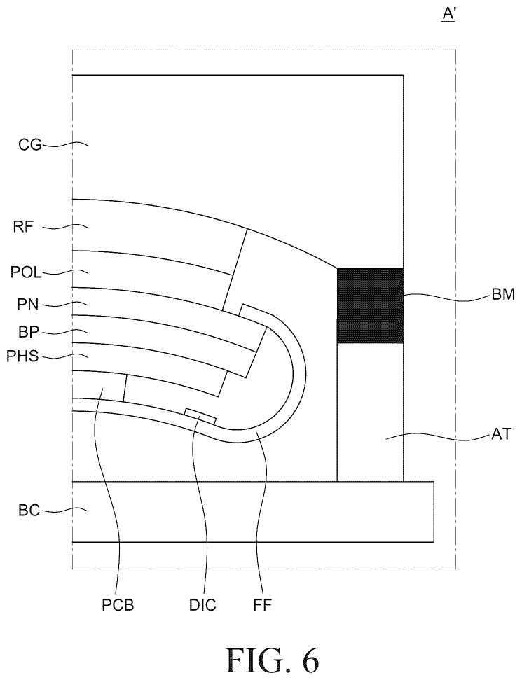

FIG. 5 is a cross-sectional view of a display device according to another example embodiment of the present disclosure and FIG. 6 is an enlarged view of an area A′ of FIG. 5. A display device 500 of FIGS. 5 and 6 has the substantially same configurations as the display device 100 of FIGS. 1 to 4B except that an optical film RF is further included, so that a redundant description will be omitted or may be briefly provided.

Referring to FIGS. 5 and 6, a display device 500 according to another example embodiment of the present disclosure can further include an optical film RF disposed between the polarization plate POL and the cover member CG.

The optical film RF can be disposed so as to correspond to a concave surface of the bottom surface of the cover member CG. Therefore, the optical film RF can have a shape recessed from both side portions to the center portion so as to correspond to the concave surface of the cover member. A top surface of the optical film RF can be bonded to the bottom surface of the cover member CG and a bottom surface can be bonded to the top surface of the polarization plate POL. Therefore, the top surface of the optical film RF can correspond to a shape of the bottom surface of the cover member CG and the bottom surface can correspond to a shape of the top surface of the polarization plate POL. At this time, an upper adhesive layer can be disposed between the top surface of the optical film RF and the bottom surface of the cover member CG and a lower adhesive layer can be disposed between the bottom surface of the optical film RF and the top surface of the polarization plate POL. The upper adhesive layer and the lower adhesive layer can be optically clear adhesives (OCA), but are not limited thereto.

The optical film RF can have the same size as the polarization plate POL, but is not limited hereto. At this time, the same size means that an area, a shape, and a horizontal or vertical length of each configuration on the plane are the same. However, thicknesses of the optical film RF and the polarization plate POL can be different from each other.

The optical film RF can be a transparent film, but is not limited thereto.

The optical film RF can refract the light discharged from the display panel PN toward both side surface directions of the cover member CG. The optical film RF can have a refractive index larger than that of the polarization plate POL. Further, the refractive index of the optical film RF can be larger than those of the upper adhesive layer and the lower adhesive layer.

The display device 500 according to another example embodiment of the present disclosure includes a cover member CG which has a flat top surface and a bottom surface at least partially formed of a concave surface recessed toward the top surface. Therefore, a part of light discharged from the display panel PN can be directed toward the side surface direction. Therefore, the display area DA′ visible to the user in the driving state of the display device 500 can be larger than the display area DA visible to the user in the non-driving state. For example, in the display device 500 according to another example embodiment of the present disclosure, a bezel area which is actually visible can be reduced more than a bezel area which is actually disposed.

Further, the display device 500 according to another example embodiment of the present disclosure can further include an optical film RF having a refractive index which is larger than those of adjacent surrounding components. Accordingly, the light discharged from the display panel PN can be further refracted to the both side surface directions. Therefore, the display area DA′ which is visible to the user in the driving state of the display device 500 is larger than the display area DA which is visible to the user in the non-driving state and a bezel area which is actually visible can be further reduced.

By doing this, the width of the bezel which is actually disposed is disposed to be larger so that a protruding amount of the bending area BA of the flexible film FF which protrudes to the outside of the panel may not be physically reduced. By doing this, the stress applied to the bending area BA is further reduced and the crack caused by the stress can be further suppressed.

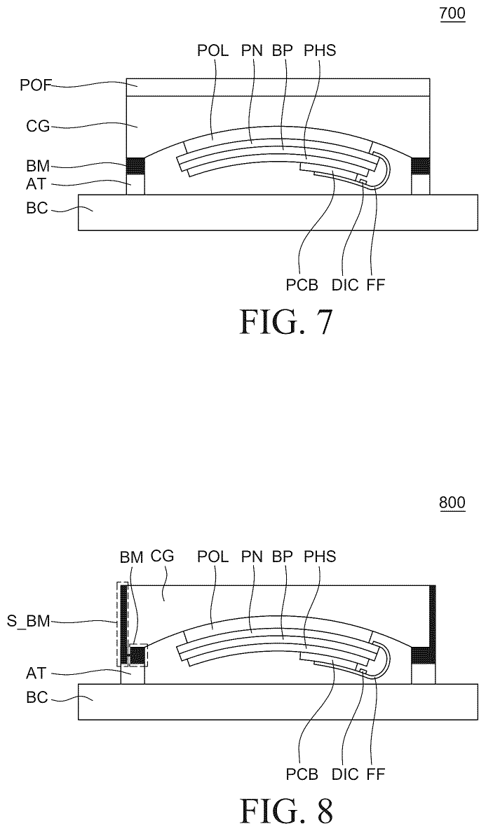

FIG. 7 is a cross-sectional view of a display device according to still another example embodiment of the present disclosure. A display device 700 of FIG. 7 has the substantially same configurations as the display device 100 of FIGS. 1 to 4A except that a polarization coating film POF is further disposed, so that a redundant description will be omitted or may be briefly provided.

Referring to FIG. 7, a polarization coating film POF can be disposed on a top surface of the cover member CG in the display device 700 of another example embodiment of the present disclosure.

The polarization coating film POF can be disposed on the top surface of the cover member CG and can be formed by coating a polarization material, but is not limited thereto.

The polarization coating film POF can have the same size as the top surface of the cover member CG and can be disposed to completely overlap the top surface of the cover member CG. For example, both ends of the polarization coating film POF can match both ends of the cover member CG.

A bottom surface of the polarization coating film POF can have a flat shape corresponding to the top surface of the cover member CG, and a top surface of the polarization coating film can also have the same shape as the bottom surface of the polarization coating film.

The polarization coating film POF can be formed of a material which performs a polarization function, but a type thereof is not limited.

The display device 700 according to still another example embodiment of the present disclosure includes a cover member CG which has a flat top surface and a bottom surface at least partially formed of a concave surface recessed toward the top surface. Therefore, a part of light discharged from the display panel PN can be directed toward the side surface direction. By doing this, the display area DA′ visible to the user in the driving state of the display device 700 can be larger than the display area DA visible to the user in the non-driving state of the display device 700. Accordingly, a bezel area which is actually visible can be reduced more than the bezel area which is actually disposed.

The display device 700 according to still another example embodiment of the present disclosure further includes the polarization coating film POF on the top surface of the cover member CG. Therefore, a path of light discharged from the display panel PN to travel toward both side surface directions of the display device 700 can be changed to the front surface direction of the field of view. Therefore, a screen distortion which can be generated on both side portions of the display device 700 as light travels toward both side surface directions of the display device 700 can be suppressed.

Further, in the display device 700 according to still another example embodiment of the present disclosure, a length of the polarization coating film POF having the flat shape can be equal to a length of the top surface of the cover member CG. Accordingly, light emitted from the display panel PN can be suppressed from being leaked to the side surface without reaching the top surface of the cover member CG. Therefore, the luminance degradation or the screen distortion on both side portions of the display panel PN can be suppressed.

Together with this, in the display device 700 according to another example embodiment of the present disclosure, a sufficient bezel area can be disposed so as to ensure the protruding amount of the bending area BA of the flexible film FF which protrudes to the outside of the panel. Therefore, the stress applied to the bending area BA is reduced and the crack caused by the stress can be suppressed.

FIG. 8 is a cross-sectional view of a display device 800 according to still another example embodiment of the present disclosure. A display device 800 of FIG. 8 has the same configurations as the display device 100 of FIGS. 1 to 4B except that an additional black matrix S_BM is further included, so that a redundant description will be omitted or may be briefly provided.

Referring to FIG. 8, the display device 800 of FIG. 8 can further include an additional black matrix S_BM on a side surface of the cover member CG. The additional black matrix S_BM extends from the black matrix BM disposed on the bottom surface of the cover member CG to the side surface of the cover member CG. The additional black matrix S_BM can be disposed so as to completely cover both side surfaces of the cover member CG. For example, the additional black matrix S_BM can be connected to the first part P1 and the second part P2 to be disposed. An end of the additional black matrix S_BM can match the top surface of the cover member CG.

Further, a thickness of the additional black matrix S_BM disposed on the side surface of the cover member CG is smaller than a thickness of the black matrix BM disposed on the bottom surface of the cover member CG. At this time, the thickness of the additional black matrix S_BM refers to a thickness in the horizontal direction on the cross-section and the thickness of the black matrix BM refers to a thickness of the vertical direction on the cross-section.

The display device 800 according to still another example embodiment of the present disclosure includes a cover member CG in which at least a part of a bottom surface is formed of a concave surface recessed toward the top surface. Therefore, light discharged from the display panel PN can be directed toward the side surface direction of the display device 800. Therefore, the display area DA′ visible to the user in the driving state of the display device 800 can be larger than the display area DA visible to the user in the non-driving state. Accordingly, a bezel area which is actually visible is reduced more than the bezel area which is actually disposed.

The display device 800 according to still another example embodiment of the present disclosure can further include an additional black matrix S_BM extending from the black matrix BM on the side surface of the cover member CG. Therefore, the display panel PN has a shape recessed toward the center portion so that when light emitted from the display panel PN is directed to both side portions of the display device 800, the light can be suppressed from being leaked toward the side surface without reaching the top surface of the cover member CG. Therefore, the luminance degradation or the screen distortion problem generated on both side portions of the display device 800 due to light which is leaked toward the side surface of the cover member CG can be suppressed.

Accordingly, the display device 800 according to the example embodiment of the present disclosure can ensure a sufficient bezel area so that it is not necessary to physically reduce a protruding amount of the bending area BA of the flexible film FF which protrudes to the outside of the display panel PN. Therefore, the stress applied to the bending area BA is minimized and the crack caused by the stress can be suppressed.

The example embodiments of the present disclosure can also be described as follows:

According to an aspect of the present disclosure, there is provided a display device. The display device comprises a display panel including a plurality of sub pixels, a cover member disposed on the display panel, a flexible film bonded to a top surface of the display panel at one side of the display panel and bent toward a bottom surface of the display panel, wherein at least a part of a bottom surface of the cover member is a concave surface recessed toward a top surface of the cover member and the top surface of the cover member has a flat shape.

A shape of the display panel can correspond to a shape of the bottom surface of the cover member.

The display panel can be bonded to the concave surface of the bottom surface of the cover member.

The concave surface can be recessed toward a center portion from an area in which the flexible film is disposed and an opposite area of the area in which the flexible film is disposed.

The display device can further comprise a polarization plate disposed between the display panel and the cover member, and an optical film disposed between the polarization plate and the cover member.

A refractive index of the optical film can be larger than that of the polarization plate.

The display device can further comprise an upper adhesive layer disposed between the optical film and the polarization plate, and a lower adhesive layer disposed between the optical film and the cover member, wherein a refractive index of the optical film can be larger than a refractive index of the upper adhesive layer and a refractive index of the lower adhesive layer.

The display device can further comprise a black matrix in contact with the bottom surface of the cover member and disposed so as to enclose the display panel.

The bottom surface of the cover member can further include a flat surface enclosing the concave surface and the black matrix can be disposed on the flat surface.

The black matrix can include a first part adjacent to the flexible film, a second part opposite to the first part, and a third part connecting the first part and the second part, and widths of the first part and the second part can be larger than a width of the third part.

The display device can further comprise an additional black matrix disposed on a side surface of the cover member.

The additional black matrix can be connected to the first part and the second part.

A thickness of the additional black matrix can be smaller than a thickness of the black matrix.

The display device can further comprise a polarization coating film disposed on the top surface of the cover member.

Although the example embodiments of the present disclosure have been described in detail with reference to the accompanying drawings, the present disclosure is not limited thereto and can be embodied in many different forms without departing from the technical concept of the present disclosure. Therefore, the example embodiments of the present disclosure are provided for illustrative purposes only but not intended to limit the technical concept of the present disclosure. The scope of the technical concept of the present disclosure is not limited thereto. Therefore, it should be understood that the above-described example embodiments are illustrative in all aspects and do not limit the present disclosure. All the technical concepts in the equivalent scope of the present disclosure should be construed as falling within the scope of the present disclosure.

What is claimed is:

1. A display device, comprising:
a display panel including a plurality of sub pixels;
a cover member disposed on the display panel;
a flexible film bonded to a top surface of the display panel at one side of the display panel and bent toward a bottom surface of the display panel,
wherein at least a part of a bottom surface of the cover member is a concave surface recessed toward a top surface of the cover member, and
wherein the top surface of the cover member has a flat shape.

2. The display device according to claim 1, wherein a shape of the display panel corresponds to a shape of the bottom surface of the cover member.

3. The display device according to claim 2, wherein the display panel is bonded to the concave surface of the bottom surface of the cover member.

4. The display device according to claim 1, wherein the concave surface is recessed toward a center portion from an area in which the flexible film is disposed and an opposite area of the area in which the flexible film is disposed.

5. The display device according to claim 1, further comprising:
a polarization plate disposed between the display panel and the cover member.

6. The display device according to claim 5, wherein the polarization plate is bonded to the concave surface of the bottom surface of the cover member.

7. The display device according to claim 6, wherein a length of a side of the polarization plate adjacent to the flexible film to an opposite side is smaller than a length of the display panel.

8. The display device according to claim 5, further comprising:
an optical film disposed between the polarization plate and the cover member.

9. The display device according to claim 8, wherein a refractive index of the optical film is larger than a refractive index of the polarization plate.

10. The display device according to claim 8, further comprising:
an upper adhesive layer disposed between the optical film and the polarization plate; and
a lower adhesive layer disposed between the optical film and the cover member,
wherein a refractive index of the optical film is larger than a refractive index of the upper adhesive layer and a refractive index of the lower adhesive layer.

11. The display device according to claim 1, further comprising:
a black matrix in contact with the bottom surface of the cover member and configured to enclose the display panel.

12. The display device according to claim 11, wherein the bottom surface of the cover member further includes a flat surface enclosing the concave surface, and
wherein the black matrix is disposed on the flat surface of the bottom surface of the cover member.

13. The display device according to claim 11, wherein the black matrix includes:
a first part disposed adjacent to the flexible film;
a second part disposed opposite to the first part; and
a third part connecting the first part and the second part, and
wherein widths of the first part and the second part are larger than a width of the third part.

14. The display device according to claim 13, further comprising:
an additional black matrix disposed on a side surface of the cover member.

15. The display device according to claim 14, wherein the additional black matrix is connected to the first part and the second part.

16. The display device according to claim 14, wherein a thickness of the additional black matrix is smaller than a thickness of the black matrix.

17. The display device according to claim 1, further comprising:
a polarization coating film disposed on the top surface of the cover member.

18. The display device according to claim 17, wherein the polarization coating film has a same size as the top surface of the cover member.

19. The display device according to claim 18, wherein a bottom surface of the polarization coating film has a flat shape corresponding to the top surface of the cover member, and
wherein a top surface of the polarization coating film has a same shape as the bottom surface of the polarization coating film.
